(19) United States
(12) Patent Application Publication
(10) Pub. No.: US 2017/0109233 A1
(43) Pub. Date: Apr. 20, 2017

(54) DATA ENCODING USING AN ADJOINT MATRIX

(71) Applicant: SANDISK TECHNOLOGIES INC., PLANO, TX (US)

(72) Inventor: ISHAI ILANI, DOLEV (IL)

(21) Appl. No.: 14/918,142

(22) Filed: Oct. 20, 2015

(51) Int. Cl. G06F 11/10; H03M 13/00

(52) U.S. Cl. CPC G06F 11/1076; H03M 13/616

(57) ABSTRACT

An apparatus includes an encoder configured to receive data and to encode the data based on an adjoint matrix to generate a codeword. The apparatus further includes a memory coupled to the encoder and configured to store the codeword.

### FIELD OF THE DISCLOSURE

The present disclosure is generally related to electronic devices and more particularly to encoding processes for electronic devices, such as an encoding process performed by a data storage device.

### BACKGROUND

Electronic devices enable users to send, receive, store, and retrieve data. For example, communication devices may use a communication channel to send and receive data, and storage devices may enable users to store and access data. Examples of storage devices include volatile memory devices and non-volatile memory devices. Storage devices may use error correction coding (ECC) techniques to detect and correct errors in data.

To illustrate, an encoding process may include encoding user data to generate an ECC codeword that includes parity information associated with the user data. The ECC codeword may be stored at a memory, such as at a non-volatile memory of a data storage device, or the ECC codeword may be transmitted over a communication channel.

During a read process, a controller of the data storage device may receive a representation of the codeword from the non-volatile memory. The representation of the codeword may differ from the codeword due to one or more bit errors. The controller may initiate a decoding process to correct the one or more bit errors using the parity information (or a representation of the parity information). For example, the decoding process may include adjusting bit values of the representation of the codeword so that the representation of the codeword satisfies a set of parity equations specified by a parity check matrix.

As data storage density of storage devices increases, an average number of bit errors in stored data may increase (e.g., due to increased cross-coupling effects as a result of smaller device component sizes). To correct more bit errors, encoding and decoding processes may utilize more device resources, such as circuit area, power, and clock cycles. In some applications, increased use of device resources may be infeasible. For example, increasing power consumption may be infeasible in certain low-power applications. As another example, increasing an average or expected number of clock cycles used for encoding or decoding processes may be infeasible in high data throughput applications.

### BRIEF DESCRIPTION OF THE DRAWINGS

FIG. 1A is a diagram of a particular illustrative example of a system that includes a device, such as a data storage device.

FIG. 1B is a diagram of a particular illustrative example of a projection matrix.

FIG. 1C is a diagram of a particular illustrative example of parity bit computation using a parallel technique.

FIG. 1D is a diagram of a particular illustrative example of parity bit computation using a serial technique.

FIG. 1E is a diagram of a particular illustrative example of decoder circuitry including a sparse matrix multiplier.

FIG. 1F is a diagram of a particular illustrative example of a parity-check matrix having a lower triangular form.

FIG. 1G is a diagram of a particular illustrative example of a matrix having a row-gap.

FIG. 1H is a diagram of a particular illustrative example of a partition of parity-check matrix.

FIG. 2 is a diagram of particular illustrative examples of certain components that may be included in the device of FIG. 1A.

FIG. 3 is a diagram of another particular illustrative example of certain components that may be included in the device of FIG. 1A.

FIG. 4 is a diagram of a particular illustrative example of a method of operation that may be performed by the device of FIG. 1A.

FIG. 5 is a diagram of another particular illustrative example of a method of operation that may be performed by the device of FIG. 1A.

### DETAILED DESCRIPTION

An encoder in accordance with the disclosure may perform an encoding process that avoids storing an inverse of the parity portion of the parity check matrix, and avoids straight forward computation of the product Hₚ⁻¹y^{T} and computes p^{T}in an efficient and low complexity computation, where Hₚ is the parity portion of a parity check matrix, p^{T} is a vector of the parity bits, and y^{T} is a pre-calculated vector. To illustrate, certain conventional devices decode data using a parity check matrix and encode data using an inverse of the parity portion of the parity check matrix. In some cases, the parity check matrix is large and use of an inverse of the parity portion of the parity check matrix consumes device resources, such as circuit area, power, and clock cycles. For example, an encoder in accordance with the disclosure may include matrix inverse circuitry having a two-stage configuration, thus avoiding straight forward computation of the product Hₚ⁻¹y^{T}.

Instead of storing the inverse of the parity portion of the parity check matrix, the encoder may store an adjoint matrix over the ring of circulants of the parity portion of the parity check matrix. During an encoding process, a multiplication operation may be performed by multiplying the adjoint matrix and a first set of values to generate a second set of values. If certain conditions are met, the density of the adjoint matrix is significantly less than the density of the inverse of the parity portion of the parity check matrix, and as a result the multiplication operation may be simplified (e.g., lower complexity and more efficient) by using the adjoint matrix instead of the inverse of the parity portion of the parity check matrix.

The encoding process may also include performing one or more determinant inverse operations based on the second set of values to generate a third set of values (e.g., a set of parity values). The one or more determinant inverse operations may include multiplying a ring determinant matrix and the second set of values to generate the third set of values. Because the size of the ring determinant matrix is less than the size of the parity portion of the parity check matrix, the determinant inverse operations are less complex than the operations of multiplying by the inverse of the parity portion of the parity check matrix. As used herein, “size” may indicate a number of rows and columns of a matrix, and “order” may indicate the minimal integer n such that Aⁿ=I.

In an illustrative implementation, the encoder includes a first stage and a second stage. The first stage may be configured to receive the first set of values and to generate the second set of values, such as by multiplying an adjoint of a matrix (e.g., a predefined square block matrix) and the first set of values. The second stage may be configured to receive the second set of values and to generate the third set of values (e.g., a set of parity values), such as by multiplying the second set of values by a determinant inverse of the matrix. Operation of the encoder may be less complex (e.g., lower complexity and more efficient) as compared to certain encoders that perform matrix inversion operations of the parity matrix to generate parity values during an encoding process. For example, “splitting” a matrix inversion operation into multiple stages that utilize the adjoint matrix and the ring determinant matrix may be less computationally complex (and more resource efficient) as compared to use of the inverse matrix.

Particular aspects of the disclosure are described below with reference to the drawings. In the description, common or similar features may be designated by common reference numbers. As used herein, “exemplary” indicates an example, an implementation, and/or an aspect, and should not be construed as indicating a preference or a preferred implementation.

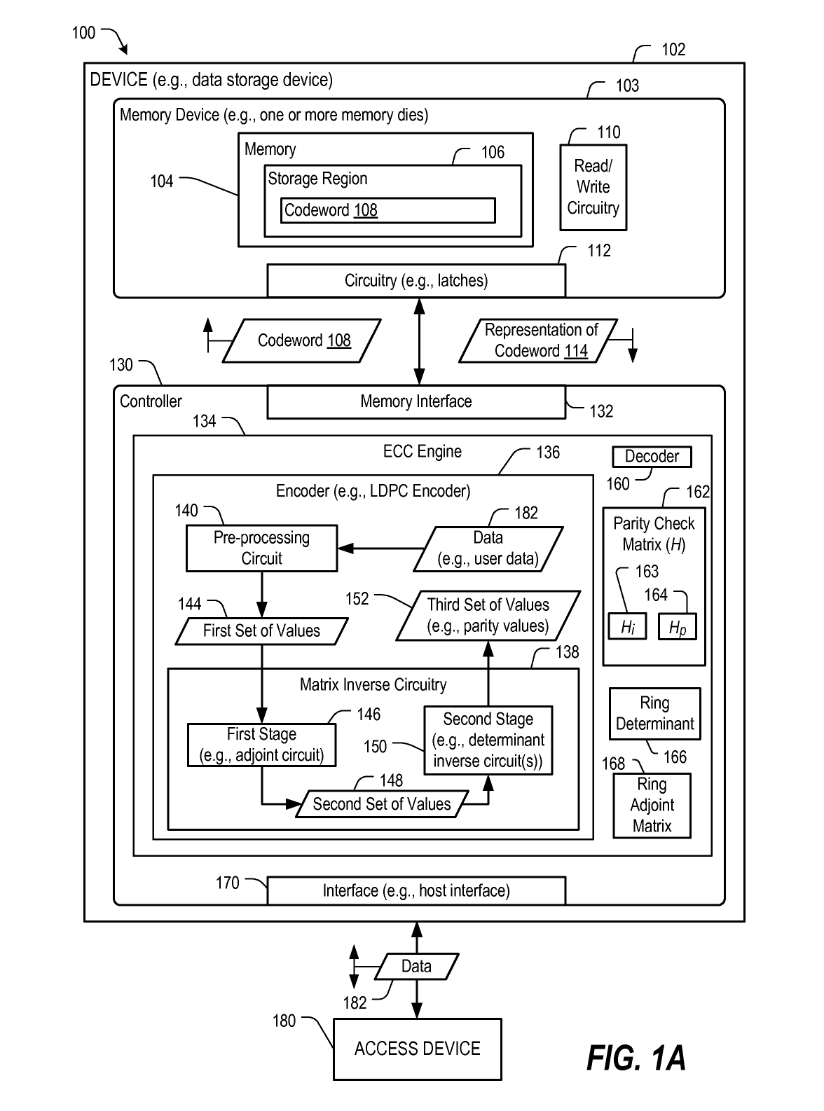

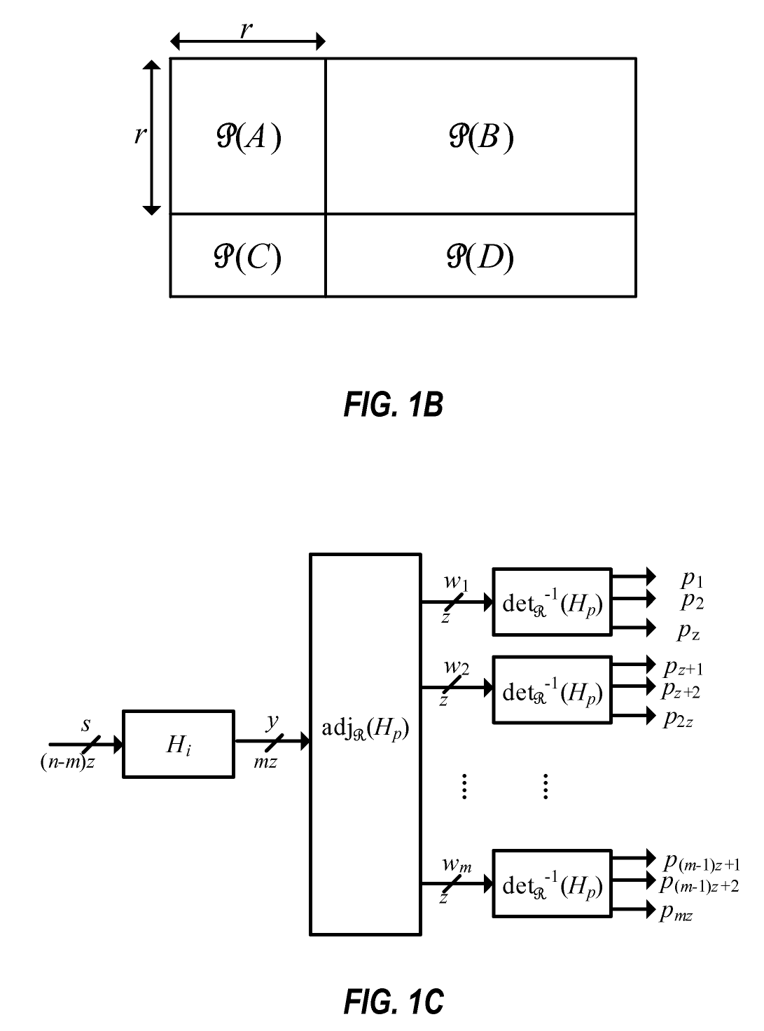

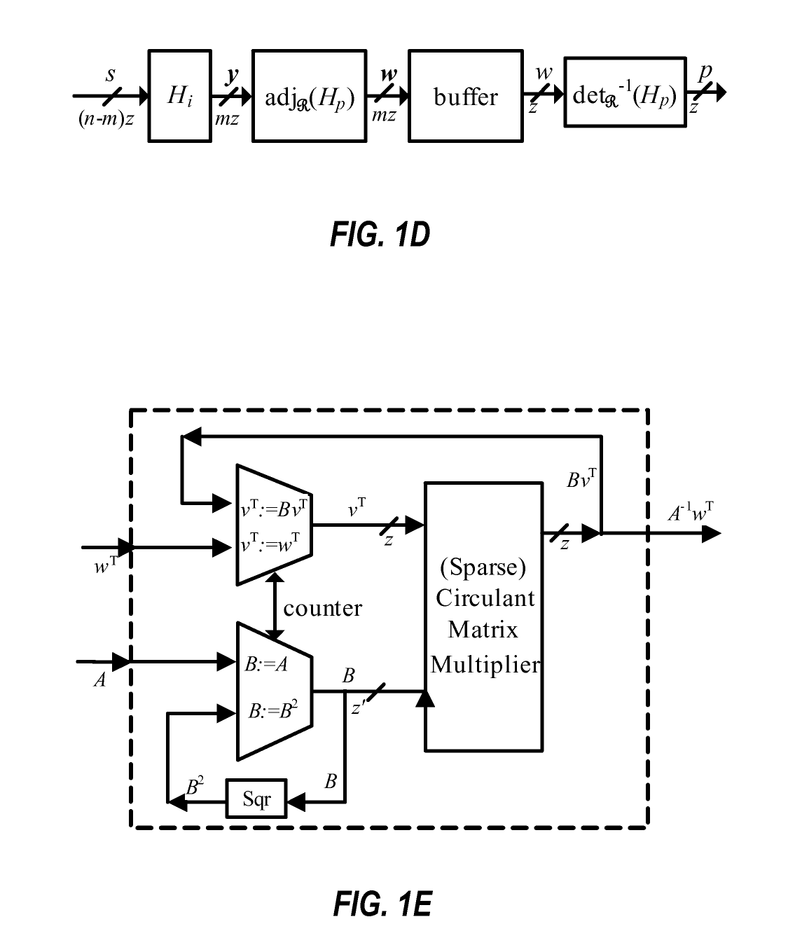

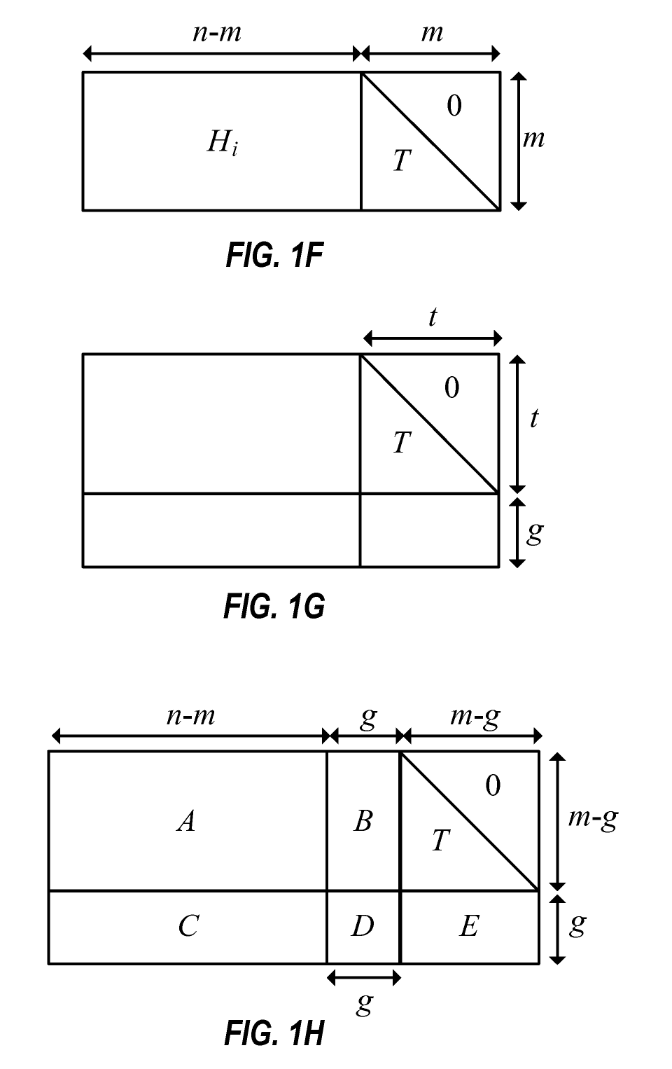

Referring to FIG. 1A, a particular illustrative example of a system is depicted and generally designated 100. The system 100 includes a device 102 and an access device 180 (e.g., a host device or another device).

The device 102 may include a memory device 103. The memory device 103 may include one or more memory dies (e.g., one memory die, two memory dies, sixty-four memory dies, or another number of memory dies). The memory device 103 may include a memory 104, read/write circuitry 110, and circuitry 112 (e.g., a set of latches).

The memory 104 may include a non-volatile array of storage elements of a memory die. The memory 104 may include a flash memory (e.g., a NAND flash memory) or a resistive memory, such as a resistive random access memory (ReRAM), as illustrative examples. The memory 104 may have a three-dimensional (3D) memory configuration. As used herein, a 3D memory device may include multiple physical levels of storage elements (instead of having a single physical level of storage elements, as in a planar memory device). As an example, the memory 104 may have a 3D vertical bit line (VBL) configuration. In a particular implementation, the memory 104 is a non-volatile memory having a 3D memory array configuration that is monolithically formed in one or more physical levels of arrays of memory cells having an active area disposed above a silicon substrate. Alternatively, the memory 104 may have another configuration, such as a two-dimensional (2D) memory configuration or a non-monolithic 3D memory configuration (e.g., a stacked die 3D memory configuration).

The memory 104 includes one or more regions of storage elements, such as a storage region 106. An example of a storage region is a memory die. Another example of a storage region is a block, such as a NAND flash erase group of storage elements, or a group of resistance-based storage elements in a ReRAM implementation. Another example of a storage region is a word line of storage elements (e.g., a word line of NAND flash storage elements or a word line of resistance-based storage elements). A storage region may have a single-level-cell (SLC) configuration, a multi-level-cell (MLC) configuration, or a tri-level-cell (TLC) configuration, as illustrative examples. Each storage element of the memory 104 may be programmable to a state (e.g., a threshold voltage in a flash configuration or a resistive state in a resistive memory configuration) that indicates one or more values. As an example, in an illustrative TLC scheme, a storage element may be programmable to a state that indicates three values. As an additional example, in an illustrative MLC scheme, a storage element may be programmable to a state that indicates two values.

The device 102 may further include a controller 130. The controller 130 may be coupled to the memory device 103 via a memory interface 132 (e.g., a physical interface, a logical interface, a bus, a wireless interface, or another interface). The controller 130 may be coupled to the access device 180 via an interface 170 (e.g., a physical interface, a logical interface, a bus, a wireless interface, or another interface).

The controller 130 may include an error correcting code (ECC) engine 134. The ECC engine 134 may include an encoding device (e.g., an encoder 136) and a decoder 160. To illustrate, the encoder 136 and the decoder 160 may operate in accordance with a low-density parity check (LDPC) ECC technique. The encoder 136 may include an LDPC encoder (e.g., a lifted LDPC encoder), and the decoder 160 may include an LDPC decoder.

One or more of the encoder 136 or the decoder 160 may operate based on a parity check matrix 162 (H) (e.g., an LDPC parity check matrix). The parity check matrix 162 may include a first set of columns 163 (Hᵢ) associated with an information portion of an LDPC code and may further include a second set of columns 164 (Hₚ) associated with a parity portion of the LDPC code, where H=(Hᵢ|Hₚ). The second set of columns 164 may correspond to a sparse invertible matrix (i.e., Hₚ may be invertible and may include a relatively large number of zero values).

The encoder 136 may include a pre-processing circuit 140 and matrix inverse circuitry 138. The matrix inverse circuitry 138 may include a first stage 146 (e.g., an adjoint circuit) and a second stage 150 (e.g., one or more determinant inverse circuits).

During operation, the controller 130 may receive data from the access device 180 and may send data to the access device 180. For example, the controller 130 may receive data 182 (e.g., user data) from the access device 180 with a request for write access to the memory 104.

In response to receiving the data 182, the controller 130 may initiate an encoding process to encode the data 182. For example, the controller 130 may input the data 182 to the encoder 136, such as by inputting the data 182 to the pre-processing circuit 140. The pre-processing circuit 140 may be configured to generate a first set of values 144 (e.g., a vector) based on the data 182. For example, the pre-processing circuit 140 may be configured to multiply the first set of columns 163 and the data 182 to generate the first set of values 144. To further illustrate, if vᵢ indicates the data 182 and y indicates the first set of values 144, then the pre-processing circuit 140 may be configured to generate the first set of values 144 based on y^{T}=Hᵢ·vᵢ^{T}. Alternatively or in addition, the pre-processing circuit 140 may be configured to operate in accordance with equation (27), below.

The matrix inverse circuitry 138 may receive the first set of values 144 from the pre-processing circuit. For example, the first stage 146 may be configured to receive the first set of values 144 from the pre-processing circuit 140. The first stage 146 may be configured to generate a second set of values 148 based on the first set of values and further based on a ring adjoint matrix 168 of a matrix, such as a predefined square block matrix (e.g., second set of columns 164). As used herein, an “adjoint” (also referred to as “adjoint matrix” and “ring adjoint”) of a matrix refers to a transpose of a cofactor matrix of the matrix. To further illustrate, if w indicates the second set of values 148 (e.g., a positive integer number m of vectors w₁, w₂, . . . wₘ) and A indicates a matrix (e.g., the second set of columns 164, or Hₚ), then the matrix inverse circuitry 138 may be configured to generate the second set of values 148 based on w=adj_{R}(A)·y^{T} (where adj_{R}(A) indicates the ring adjoint of A). A may correspond to a sparse matrix that is comprised of cyclic permutation matrices.

In an illustrative implementation, each non-zero entry of the matrix A (e.g., the second set of columns 164) may correspond to a circulant matrix of weight 1 which is also known as a cyclic permutation matrix, and each cyclic permutation matrix may have a size z (e.g., a number of columns and a number of rows) that is a power of two. Each zero entry may correspond to a 0-matrix of the same size z. The first stage 146 may be configured to operate with low memory resources and limited algorithmic complexity as a function of the size of each cyclic permutation matrix. This follows from the fact that under suitable conditions, the density of adj_{R}(A), where the adjoint operation is performed as a ring adjoint over the ring of circulant matrices, is significantly lower than the density of the inverse of A.

The second stage 150 may be configured to receive the second set of values 148 from the first stage 146 and to generate a third set of values 152 based on the second set of values and further based on a ring determinant 166 of the matrix (e.g., the second set of columns 164). For example, the second stage 150 may be configured to multiply the ring determinant 166 and second set of values 148 to generate the third set of values 152. The third set of values 152 may include parity values associated with the data 182.

To further illustrate, if pᵢ indicates the third set of values 152 (e.g., a positive integer number m of parity vectors p₁, p₂, . . . pₘ each having a dimension z) and det_{R}⁻¹(A) corresponds to the ring determinant 166, then the second stage 150 may be configured to generate the third set of values 152 based on pᵢ^{T}=det_{R}⁻¹(A)·wᵢ^{T} (where det_{R}¹(A) indicates the inverse of the determinant of A over a ring R). The third set of values 152 may be equal the first set of values 144 multiplied by an inverse of a matrix (e.g., an inverse of the second set of columns 164). In this example, p^{T}=Hₚ⁻¹·y^{T}.

The ring adjoint matrix 168 is defined over the ring R. The (i, j) minor of A may be denoted det_{R}(Aᵢⱼ) and is the determinant over R of the (m−1)×(m−1) matrix (or block matrix) that results from deleting the ith row (or ith block row) and the jth column (or jth block column) of A. The adjoint of A (i.e., adj(A)) is the m×m matrix whose (i, j) entry is defined by adj_{R}(A)ᵢⱼ=det_{R}(Aⱼᵢ). adj_{R}(A)·A may be expressed as:

$${adj}_{R} ( A ) \cdot A = A \cdot {adj}_{R} ( A ) = ( \begin{matrix}{det}_{R} ( A ) & & 0 \\ & & \\ 0 & & {det}_{R} ( A )\end{matrix} ) ,$$

After generating the third set of values 152, the controller 130 may store the data 182 and the third set of values 152 to the memory 104. For example, the controller 130 may combine (e.g., concatenate) the data 182 and the third set of values 152 to form a codeword 108. The controller 130 may send the codeword 108 to the memory device 103 to be stored at the memory 104, such as at the storage region 106. The memory device 103 may receive the codeword 108 at the circuitry 112 and may use the read/write circuitry 110 to write the codeword 108 to the memory 104, such as at the storage region 106.

The device 102 may initiate a read process to access the codeword 108. For example, the controller 130 may receive a request for read access from the access device 180. As another example, the controller 130 may initiate another operation, such as a compaction process to copy the codeword 108 from the storage region 106 to another storage region of the memory 104. During the read process, memory device 103 may use the read/write circuitry 110 to sense the codeword 108 to generate a representation 114 of the codeword 108.

The controller 130 may input the representation 114 of the codeword 108 to the decoder 160 to decode the representation 114 of the codeword 108. For example, the decoder 160 may adjust values of the representation 114 of the codeword 108 during an iterative decoding process so that the representation 114 of the codeword 108 satisfies a set of equations specified by the parity check matrix 162 (i.e., until the representation 114 converges to a valid codeword). Alternatively, if the decoding process fails to converge, the decoding process may “time out” (e.g., after a particular number of decoding iterations), which may result in an uncorrectable error correcting code (UECC) error.

Use of the ring adjoint matrix 168 enables generation of the third set of values 152 without storing the inverse of a matrix (e.g., Hₚ⁻¹), and without straight forward computation of Hₚ⁻¹y^{T}. Avoiding direct computation of the inverse product may reduce computational complexity of a process (e.g., an encoding process). For example, adj_{R}(A) may be sparse and may have a smaller density compared to the density of the inverse of A. Further, using the ring adjoint matrix 168 enables generation of the third set of values 148 with lower complexity than a direct computation of the first set of values 144 multiplied by the inverse of the matrix (e.g., Hₚ⁻¹).

In some implementations, the device 102 of FIG. 1A corresponds to a data storage device. It should be appreciated that the device 102 may be implemented in accordance with one or more other applications. For example, in some applications, a communication device (e.g., a transmitter and/or a receiver) may include or be coupled to the encoder 136 and the memory 104. The communication device may send data and/or receive data using a communication network (e.g., a wired communication network or a wireless communication network). As an example, the communication device may send data encoded by the encoder 136 (e.g., the codeword 108) to another communication device using the communication network.

To further illustrate, certain illustrative aspects are described with reference to FIGS. 1B-1H. It should be appreciated that the aspects described with reference to FIGS. 1B-1H are illustrative and are not intended to limit the scope of the disclosure.

### PPI Theorem

Let [symbol] denote the ring GF(2)[x] generated by a single element x over the Galois field GF(2). Since [symbol] is generated by a single element, [symbol] is a commutative ring. If x has order of z=2^{l}, i.e. x^{z}= [symbol] , where [symbol] is the multiplicative unit of [symbol] , then the mapping [symbol] : [symbol] → [symbol] defined by [symbol] (y)=y^{z} is a projection (i.e., [symbol] ²= [symbol] ) that maps invertible elements of [symbol] to [symbol] and non-invertible elements to [symbol] . This follows from the fact that each Y∈ [symbol] may be represented as

Y=Σᵢ₌₀^{z-1}αᵢxⁱ, α*∈ GF(2) (1)

and therefore

[symbol]

(Y)=Y²^{^{l}}=(Σᵢ₌₀^{z-1}αᵢxⁱ)²^{^{l}}=Σᵢ₌₀^{z-1}αᵢxⁱ²^{^{l}}=Σᵢ₌₀^{z-1}αᵢ(x²^{^{l}})ⁱ=(Σᵢ₌₀^{z-1}αᵢ) [symbol] (2)

Equation (2) indicates that Y is invertible if its weight is odd, and Y is not invertible if its weight is even, where the weight of Y is the number of non-zero α-s in its representation. Note that [symbol] ( [symbol] ) may be identified with GF(2). The projection [symbol] may be extended to matrix rings over [symbol] by defining [symbol] (A) to be the matrix whose elements are element-wise z-powers of the elements of A. Note that for z=2^{l} [symbol] (A) is a linear transformation, i.e.,

[symbol]

(AB+C)= [symbol] (A) [symbol] (B)+ [symbol] (C) (3)

whenever AB+C is defined. Since [symbol] is a commutative ring the definitions of determinant, and adjucate (adjoint) matrix extend to Mm( [symbol] ) in a natural way. The determinant (adjucate matrix) over the ring [symbol] is denoted by de [symbol] (ad [symbol] ).

Lemma: Let [symbol] ,x, [symbol] be as above. Then for any square matrix A over

[symbol]

[symbol]

(de [symbol] (A))=det( [symbol] (A)) (4)

where the determinant on the right hand side may be considered as a field determinant over GF(2) by identifying [symbol] (A) as a matrix over GF(2).

Proof Let Sₘ denote the symmetric group on 1, 2, . . . , m}. For any A∈Mₘ( [symbol] ) let a_{i,j} denote the (i j) element of A. Since z=2^{l} and R is commutative, then

[symbol]

(de [symbol] (A))=(Σ_{π∈S}_{ₘ} Πᵢ₌₁^{m}a_{i,π(i)})^{z}=Σ_{π∈S}_{ₘ} Πᵢ₋₁^{m}a_{i,π(i)}^{z}=det( [symbol] (A)). (5)

A proof of the projection-preserving-invertability (PPI) theorem may be used to show that [symbol] is a projection-preserving-invertability (PPI) transformation.

PPI Theorem: Let [symbol] , [symbol] be as above, and let x be a matrix of size z×z over GF(2) such that x^{z}=I_{z}. Then, a matrix A∈Mₘ( [symbol] ) is invertible if and only if [symbol] (A) is invertible as a matrix in Mₘ(GF(2)).

Proof: If [symbol] (A) is invertible, then det( [symbol] (A))=1, thus according to the lemma [de [symbol] (A)]^{z}=1, and thus det(de [symbol] (A))=1. Using the formula

det(A)=det(de [symbol] (A)) (6)

it may be determined that A is invertible. If [symbol] (A) is not invertible, then det( [symbol] (A))=0, thus [de [symbol] (A)]^{z}=0, and det(de [symbol] (A))=0. Thus, A is not invertible and the proof is complete.

If A is invertible, then A is invertible both as an m×m matrix over [symbol] and as an mz×mz matrix over GF(2). When [symbol] (A) is invertible a constructive proof may be provided. Let [symbol] (A) denote the m×m block matrix

$$𝒟 ( A ) = diag ( \underbrace{{det}_{ℛ} ( A ) , {det}_{ℛ} ( A ) , … , {det}_{ℛ} ( A )}_{m times} ) . \qquad ( 7 )$$

If [symbol] (A) is invertible, then by the preceding lemma de [symbol] (A) is invertible over [symbol] , so the inverse of A may be explicitly derived from the formula

ad [symbol] (A)A=Aad [symbol] (A)= [symbol] (A) (8)

and the inverse A⁻¹ is

A⁻¹= [symbol] ⁻¹(A)ad [symbol] (A)=ad [symbol] (A) [symbol] ⁻¹(A). (9)

The PPI theorem may also be applied to simplify the computation of the rank over GF(2) of any matrix H that is a matrix of size mz×nz over GF(2) and that may also be considered as a block matrix of size m×n over [symbol] . To illustrate, consider the matrix [symbol] (H) as a m×n matrix over GF(2). If [symbol] (H) has rank r, then rows and columns of [symbol] (H) may be permutated to obtain an invertible r×r matrix in its upper left corner, such as depicted in FIG. 1B. Using the PPI theorem one may prove that

rank(H)=r·z+rank(CA⁻¹B+D). (10)

The computation of A⁻¹ and the matrix products CA⁻¹B may be performed based on the circulant structure of the matrices, thus the rank computation may be performed in low complexity.

### Design of QC-LDPC Codes Via PPI Theorem

The PPI theorem may also be used to determine quasi-cyclic LDPC (QC-LDPC) codes. A QC-LDPC code is associated with a parity-check matrix H (e.g., the parity check matrix 162 of FIG. 1A). For certain QC-LDPC codes, H may be a mz×nz matrix over GF(2). H may also be considered as a block matrix of size m×n where each block is a circulant matrix of size z×z.

The set of circulant matrices may be described in various ways. In one example, a set of circulant matrices is the underlying set of the ring [symbol] =GF(2)[x], where x is a cyclic permutation of the columns of the z×z identity matrix by one column to the right. So the first row of x is (0,1,0, . . . , 0 ), and each row is a cyclic shift to the right of the preceding row (the last row is (1,0,0, . . . , 0), which is the only row where the cyclic nature of the shift is apparent). The columns of H are partitioned into a first set and a second set (e.g., the first set of columns 163 and the second set of columns 164 of FIG. 1A). The first set is associated with the information bits of the code, and the second set is associated with the parity bits of the code. Certain LDPC techniques may design H of full rank, such that the parity portion of H is invertible. Certain other LDPC techniques may be applied. For example, certain LDPC constraints may be avoided, such as LDPC constraints leading to short cycles in the Tanner graph representation of the code. If z=2^{l}, then the conditions of the PPI theorem are satisfied, and if [symbol] (H) is full rank, then so is H. The partitioning of a full rank H may be performed such that the parity portion is invertible. The individual circulants in H may be modified so long as invertability of the circulants in the parity portion of H is preserved (i.e., invertible circulants may be replaced by invertible circulants and non-invertible circulants may be replaced by non-invertible circulants).

Counter example: If the conditions of the PPI theorem are not satisfied then there are counter examples to the PPI theorem. To illustrate, consider

$$x = ( \begin{matrix}0 & 1 & 0 \\ 0 & 0 & 1 \\ 1 & 0 & 0\end{matrix} ) \qquad ( 11 )$$

and set

$$A = ( \begin{matrix}I & x & {x}^{2} \\ I & I & 0 \\ 0 & I & I\end{matrix} ) , 𝒫 ( A ) = ( \begin{matrix}1 & 1 & 1 \\ 1 & 1 & 0 \\ 0 & 1 & 1\end{matrix} ) \qquad ( 12 )$$

In this case, [symbol] (A) is invertible, while A is not.

### Efficient Encoding of QC-LDPC Codes Via PPI Theorem

Consider a full rank parity-check matrix H partitioned into an information portion Hᵢ and an invertible parity portion Hₚ. For a data vector s and a parity vector p the following equality holds

Hᵢs^{T}=Hₚp^{T} (13)

For convenience, vectors (e.g., s,p,y,w) may be assumed to be row vectors, and when multiplying by a matrix from the left the transpose vector is used (e.g., s^{T},p^{T},y^{T},w^{T}). It follows that a systematic encoding is given by

p^{T}=Hₚ⁻¹Hᵢs^{T} (14)

The size of H is m×n and the size of Hₚ is m×m. Therefore, Hₚ⁻¹ has a size of m×m, and Hᵢ is a sparse matrix of size m×(n−m). Accordingly, Hₚ⁻¹Hᵢ may be a non-sparse matrix of size m×(n−m). Therefore, computing the parity vector p in two steps may be more efficient than computing

p^{T}=(Hₚ⁻¹Hᵢ)s^{T}. (15)

In the first step, an auxiliary vector y may be determined based on

y^{T}=Hᵢs^{T}. (16)

In the second step, p may be determined based on

p^{T}=Hₚ⁻¹y^{T}. (17)

The determination of equation (16) may be performed using a pre-computation (or pre-calculation) operation, and the determination of equation (17) may be complex.

An encoder in accordance with the disclosure (e.g., the encoder 136 of FIG. 1A) may determine p with reduced complexity by using equation (9) and may also include “divide” or “partition” the determination of equation (17) into multiple operations, such as a first operation and a second operation (e.g., using the matrix inverse circuitry 138 of FIG. 1A).

The first operation may be performed to determine an auxiliary vector w defined as

w^{T}=ad [symbol] (Hₚ)y^{T}. (18)

The second operation may be performed to determine p according to the equation

p^{T}= [symbol] ⁻¹(Hₚ)w^{T}. (19)

If [symbol] =GF(2)[x] and x is a circulant matrix of size z×z as above, then ad [symbol] (Hₚ) may be a sparse matrix (e.g., less sparse than Hₚ, but more sparse than Hₚ⁻¹). Thus, an operation based on equation (18) may be performed with less complexity as compared to an operation based on equation (17). Further, [symbol] ⁻¹(Hₚ)w^{T} may be computed with reduced complexity if [symbol] ⁻¹(Hₚ) includes only m non-zero block matrices of size z×z each. In contrast, Hₚ⁻¹ may be a dense matrix including m² non-zero block matrices of size z×z each. The total complexity of operations performed based on equations (18) and (19) may be significantly lower than complexity of computing p based on equation (17).

A block diagram illustrating certain example operations based on equations (18) and (19) is provided in FIG. 1C. Since [symbol] ⁻¹(Hₚ) contains m copies of de [symbol] ⁻¹(Hₚ), it is also possible to implement fewer blocks of de [symbol] ⁻¹(Hₚ) and to execute a serial computation of these blocks. For example, a system implementing one unit of de [symbol] ⁻¹(Hₚ) is depicted in FIG. 1D. The de [symbol] ⁻¹(Hₚ) block in FIG. 1D may use a clock signal that is m times faster than the clock signal of the de [symbol] ⁻¹(Hₚ) blocks in FIG. 1C.

The complexity of computing a product of a random binary vector y by a known binary matrix A may be bounded by 2·sum(A), where sum(A) is the number of 1s in the matrix A. This bound may be achieved by designing a circuit that supports sum(A) bit multiplications and sum(A) bit additions at locations corresponding to 1s of A.

If the matrix Hₚ is block matrix of circulants wherein each non-zero z×z block of Hₚ is a circulant matrix of weight 1, then the complexity of computing ad [symbol] (Hₚ)y^{T} is bounded by

2·m²·z·(m−1)!. (20)

The bound may be derived by noting that each block element of ad [symbol] (Hₚ) is a ring determinant of a block matrix of size (m−1)×(m−1), and the weight of each block in the block matrix is either 0 or 1. Therefore, the weight of any product of block elements is either 0 or 1. The ring determinant is a sum of (m−1)! products, and therefore a weight of the ring determinant is bounded by (m−1)!. It follows that the sum of each block element of ad [symbol] (Hₚ) is bounded by z·(m−1)!. The matrix ad [symbol] (Hₚ) contains m² circulants and the result follows. If m=4 and z=128, then the complexity of direct computation of Hₚ⁻¹y^{T} is ˜(mz)²=512²=2¹⁸, and the complexity of computing ad [symbol] (Hₚ)y^{T} is bounded by 2m²z(m−1)!=2·16·128·6<2·16·128·8=2¹⁵. Thus, a method in accordance with the disclosure may reduce at least ⅞ of the complexity.

Computing [symbol] ⁻¹(Hₚ)w^{T} may be comprised of m computations of de [symbol] ⁻¹(Hₚ)wᵢ^{T}, where wᵢ denotes a component of the vector w. Each component contains z elements (in other words each component is a vector of length z), and there are m components, (i.e., w is a vector of length mz). The complexity of computing de [symbol] ⁻¹(Hₚ)wᵢ^{T} is bounded by

2·weight(de [symbol] (Hₚ))·z log₂(z). (21)

The bound may be derived by noting that de [symbol] (Hₚ)^{z}=1 and therefore de [symbol] (Hₚ)⁻¹=de [symbol] (Hₚ)^{z-1}. But

z−1=Σᵢ₌₀^{(log}^{₂} ^{z)-1}2ⁱ, (22)

and therefore

de [symbol] ⁻¹(Hₚ)=Σᵢ₌₀^{(log}^{₂} ^{z)-1}(de [symbol] (Hₚ))²^{ⁱ}. (23)

Since the computation may be done in characteristic 2, the weight of each of the components may be bounded by the weight of de [symbol] (Hₚ). Therefore, de [symbol] ⁻¹(Hₚ)wᵢ^{T} may be determined using log₂(z) matrix computations, where each computation is bounded by 2·weight(de [symbol] (Hₚ))·z, and the proof of equation (21) is complete. An illustrative computation of de [symbol] ⁻¹(Hₚ)wᵢ^{T} according to this method is described in equation (24):

de [symbol] ⁻¹(Hₚ)wᵢ^{T}=de [symbol] ²^{^{!−1}}(Hₚ){de [symbol] ²^{^{!−2}}(Hₚ) . . . [de [symbol] ²(Hₚ)(de [symbol] (Hₚ)wᵢ^{T})]}. (24)

A block diagram illustrating a circuit to determine de [symbol] ⁻¹(Hₚ)wᵢ^{T} according to equation (24) is depicted in FIG. 1E. In the example of FIG. 1E, the matrix de [symbol] (Hₚ) is substituted by A.

The vector w and the matrix A are input to the circuit for computing A⁻¹w^{T}. The matrix A may be a low weight circulant matrix of size z×z. At the upper multiplexer, a vector v is computed, where v is either set according to v=w, or v is set to be the first output of a circulant matrix multiplier unit (v^{T}=Bv^{T}). The computation of the vector v may be based on a counter value, where for the first clock (when the counter value=0), the first option is selected (v=w), and when counter value>0, the second option is selected (v^{T}=Bv^{T}). Similarly, at the lower multiplexer a matrix B is computed where B is either set according to B:=A, or B is set to be the second output of the circulant matrix multiplier unit (B:=B²). The decision may be based on the counter value, where for the first clock (when the counter value=0), the first option is selected, and when counter value>0, the second option is selected. After log2(z) cycles, the first output of the circulant matrix multiplier unit may hold the result A⁻¹w^{T}.

Storage of the vector v may use a storage size of z bits. The matrix A and each of its powers (e.g., A², A⁴, A⁸ etc., which may be computed during the intermediate stages of the computation) may also be stored using z bits, since a circulant matrix may be determined based on its first row.

In some cases, the matrix A and its powers may be stored using a smaller amount of memory. For example, the matrix A may be indicated using weight(A) numbers, where each of the numbers is between 0 to z−1. Therefore, A may be stored in weight(A)·log 2(z) bits. The intermediate matrices (e.g., A², A⁴, A⁸ etc.) may be indicated using a similar technique, since all of these matrices have a weight that does not exceed the weight of A.

If m=4 and z=128, and if weight(det_{R}(Hₚ))=3, the complexity of computing de [symbol] ⁻¹(Hₚ)wᵢ^{T} may be bounded by 6·128·7<2¹³. Computing de [symbol] ⁻¹(Hₚ)wᵢ^{T} directly would typically have a complexity of z²=2¹⁴. If [symbol] ⁻¹(Hₚ) includes four copies of de [symbol] ⁻¹(Hₚ), then the total complexity of computing [symbol] ⁻¹(Hₚ)w^{T} may be ≦2¹⁶. Determining Hₚ⁻¹y^{T} using a technique in accordance with equations (18) and (19) results in significant savings relative to a direct computation. Further, in some cases, (e.g. when weight(det_{R}(Hₚ)) is relatively small), then additional savings may be achieved by computing det_{R}⁻¹(Hₚ)wᵢ^{T} based on equation (24) and FIG. 1E.

### DETAILED EXAMPLE

If the parity-check matrix H is comprised of a sparse Hᵢ and an invertible sparse lower triangular Hₚ=T as depicted in FIG. 1F, then systematic encoding may be performed in complexity that is approximately twice the sum of H. First, Hᵢs^{T} may be computed in complexity of approximately the sum of Hᵢ, and then the parity bits p may be determined one by one by solving Hᵢs^{T}=Hₚp^{T} in complexity of approximately twice the sum of Hₚ. A matrix of this form may impose certain restrictions on the column degree of the right most columns, which may reduce error correction capability.

Accordingly, H may be designed as an approximate lower-triangular matrix having a small row-gap of g, such as shown in FIG. 1G (where all the diagonal elements of T are invertible). A matrix H of size m×n with a row-gap of g may be partitioned as shown in FIG. 1H, where A,C are associated with the information bits, B,D are associated with g parity bits denoted as p₁, and T,E are associated with m−g parity bits denoted as p₂.

Additional techniques to simplify encoding may include setting B=0 and selecting the non-zero elements of D to be circulants of weight 1. In this case, p₂ may be determined by solving

Tp₂^{T}=As^{T} (25)

and then p₁ may be determined directly based on

p₁^{T}=D⁻¹(Cs^{T}+Ep₂^{T}). (26)

Thus, an encoder according to the present disclosure may pre-compute

y^{T}=Cs^{T}+Ep₂^{T} (27)

(e.g., using the pre-processing circuit 140 of FIG. 1A) and may then compute

p₁^{T}=D⁻¹y^{T} (28)

using a technique in accordance with equations (18) and (19) (e.g., using the matrix inverse circuitry 138 of FIG. 1A).

Consider for example a regular (3,6) code. A parity check matrix design with B=0 and H∈M_{m×n}( [symbol] ), where the non-zero elements are circulant matrices of weight 1, can be achieved by setting g=4 and by choosing D from the set of matrices for which [symbol] (D) is

$$P ( D ) = ( \begin{matrix}0 & 1 & 1 & 1 \\ 1 & 0 & 1 & 1 \\ 1 & 1 & 0 & 1 \\ 1 & 1 & 1 & 0\end{matrix} ) . \qquad ( 0 )$$

In this example, the size of the gap matrix D may be 4z. As another example, consider a (3,6) regular code of length 12800, where n=200, m=100, and z=64. Using one or more aspects of the disclosure, one may set g=4, z=64, and encoding may be performed based on equations (25) and (26). The complexity of multiplying by A,T⁻¹,C, and E is ˜76K. The complexity of computing D⁻¹y is bounded by 22K, since the weight of each element in the adjoint matrix ad [symbol] (D) is ≦3 and the inverse determinant block includes four matrices of size 64×64, so the total complexity is 98K.

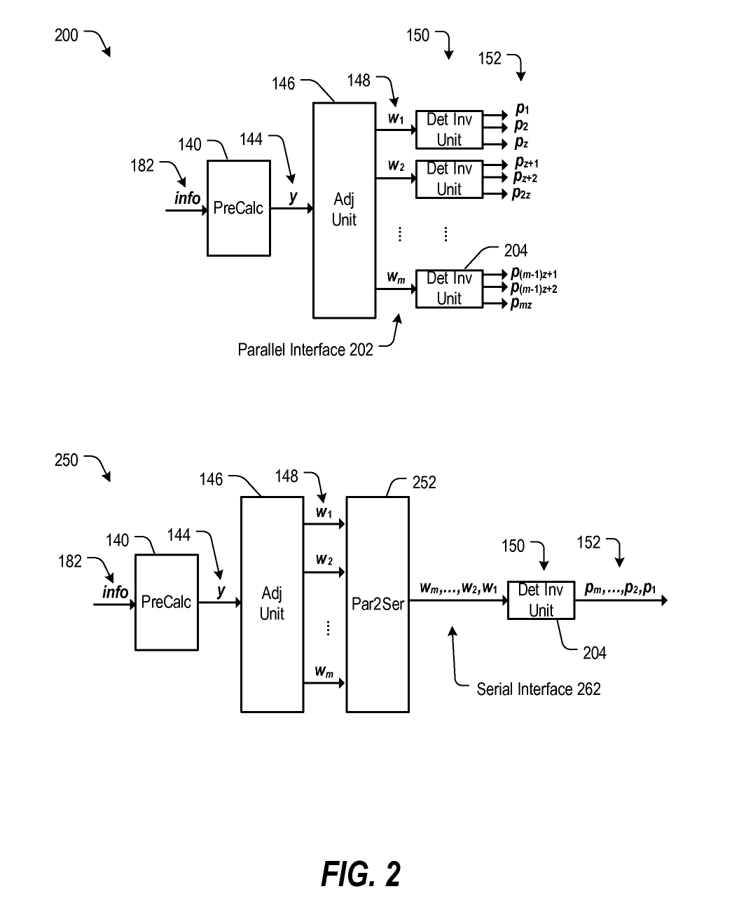

FIG. 2 illustrates a first example 200 of components that may be included in the encoder 136 of FIG. 1A. FIG. 2 also illustrates a second example 250 of components that may be included in the encoder 136 of FIG. 1A (e.g., alternatively to the first example 200). The first example 200 may correspond to the example described with reference to FIG. 1C, and the second example 250 may correspond to the example described with reference to FIG. 1D.

In the first example 200, the second stage 150 includes a set of determinant inverse circuits configured to receive the second set of values 148 from the first stage 146. To illustrate, the set of determinant inverse circuits may include a representative determinant inverse circuit 204.

The first example 200 also depicts that a parallel interface 202 may be coupled to the first stage 146 and to the set of determinant inverse circuits. The parallel interface 202 may be configured to provide the second set of values 148 in parallel to the set of determinant inverse circuits. Each determinant inverse circuit of the set of determinant inverse circuits may be configured to perform a determinant inverse operation using a corresponding value of the second set of values 148 to generate a corresponding value of the third set of values 152.

In the second example 250, the second stage 150 includes a determinant inverse circuit configured to perform a determinant inverse operation using the second set of values 148 to generate the third set of values 152. For example, the second stage 150 may include the determinant inverse circuit 204. The determinant inverse circuit 204 may be configured to operate based on a ring determinant inverse of the ring determinant 166 of FIG. 1A.

A parallel-to-serial circuit 252 may be coupled to the first stage 146. The parallel-to-serial circuit 252 configured to serialize the second set of values 148. A serial interface 262 may be coupled to the parallel-to-serial circuit 252 and to the determinant inverse circuit. The serial interface 262 may be configured to provide the second set of values 148 in series to the determinant inverse circuit.

The examples 200, 250 of FIG. 2 illustrate that a connection between the first stage 146 and the second stage 150 may be selected based on the particular application. To illustrate, the parallel configuration described with reference to the first example 200 may reduce a number of clock cycles of an encoding process, resulting in faster encoding in some applications. In other applications, the serial configuration described with reference to the second example 250 may be utilized to reduce a number of determinant inverse circuits (e.g., to reduce circuit area used by the encoder 136 of FIG. 1A).

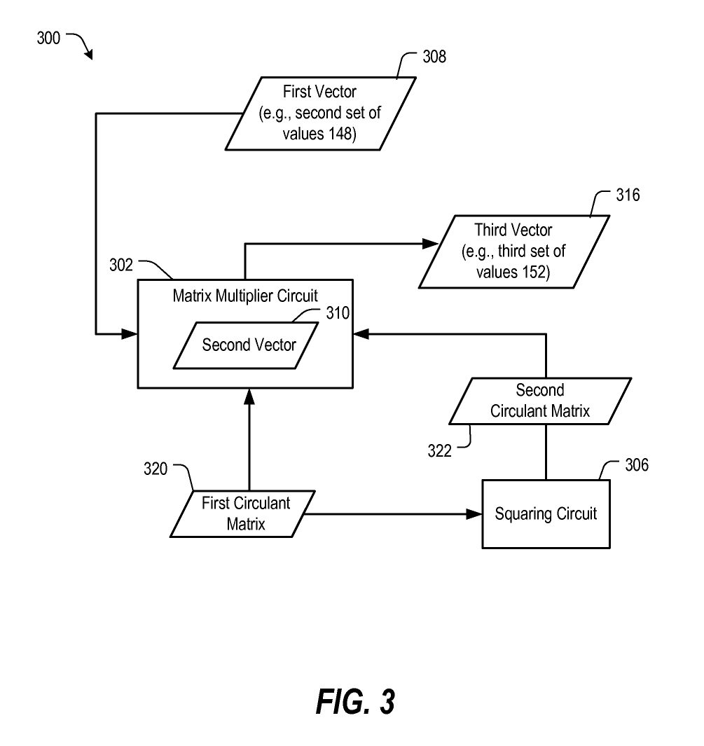

FIG. 3 illustrates a particular illustrative example of a determinant inverse circuit (e.g., the determinant inverse circuit 204 of FIG. 2). FIG. 3 depicts that the determinant inverse circuit 300 may include a matrix multiplier circuit 302 and a squaring circuit 306.

During operation, the matrix multiplier circuit 302 may receive a first vector 308. For example, the first vector 308 may correspond to the second set of values 148, and the matrix multiplier circuit 302 may receive the second set of values 148 from the first stage 146 (e.g., using the parallel interface 202 or using the parallel-to-serial circuit 252 and the serial interface 262).

The matrix multiplier circuit 302 may be configured to apply a first circulant matrix 320 to the first vector 308 to generate a second vector 310. For example, the matrix multiplier circuit 302 may multiply the first circulant matrix 320 and the first vector 308 to generate the second vector 310. The first circulant matrix 320 may be represented using (e.g., may correspond to) a ring determinant matrix, such as the ring determinant 166 of FIG. 1A.

The squaring circuit 306 may be responsive to first circulant matrix 320 to generate a second circulant matrix 322. The matrix multiplier circuit 302 may be configured to receive the second circulant matrix 322 and to apply the second circulant matrix 322 to the second vector 310 to generate a third vector 316. For example, the matrix multiplier circuit 302 may multiply the second circulant matrix 322 and the second vector 310 to generate the third vector 316. To illustrate, the third vector 316 may correspond to the third set of values 152 of FIG. 1A.

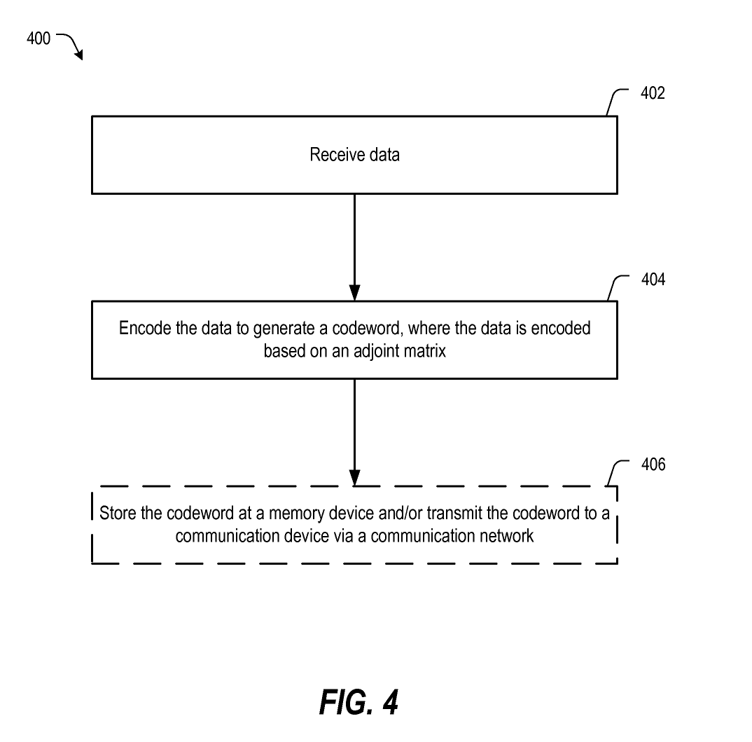

Referring to FIG. 4, a particular illustrative example of a method is depicted and generally designated 400. The method 400 may be performed at an encoding device, such as by the encoder 136 of FIG. 1A.

The method 400 includes receiving data, at 402. For example, the encoder 136 may receive the data 182 of FIG. 1A.

The method 400 further includes encoding the data to generate a codeword, where the data is encoded based on an adjoint matrix, at 404. For example, the encoder 136 may perform an encoding process to encode the data 182 to generate the codeword 108 based on the ring adjoint matrix 168.

The method 400 may also include storing the codeword at a memory that is coupled to the encoding device or transmitting the codeword to a communication device via a communication network, at 406. To illustrate, in a data storage device implementation, the codeword may be stored at the memory (e.g., a non-volatile memory). Alternatively or in addition, the codeword may be communicated to another device. For example, the codeword may be transmitted to another device via a communication network (e.g., a wired communication network or a wireless communication network).

Use of a ring adjoint matrix in connection with the method 400 of FIG. 4 enables generation of the third set of values without computing the inverse of a matrix (e.g., without computing Hₚ⁻¹ using an inversion operation). Avoiding computation of the inverse may reduce computational complexity of an encoding process. Further, using the ring adjoint matrix enables generation of the third set of values with lower complexity than a direct computation of the first set of values multiplied by the inverse of the matrix (e.g., Hₚ⁻¹).

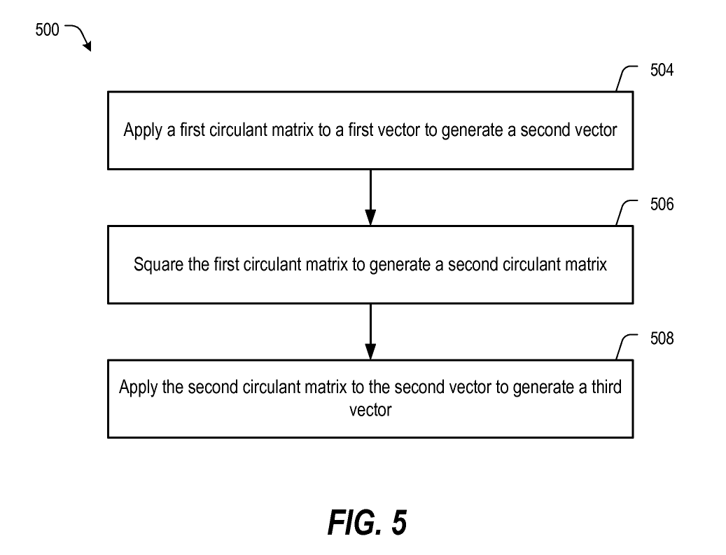

Referring to FIG. 5, a particular illustrative example of a method is depicted and generally designated 500. The method 500 may be performed at an encoder, such as by the encoder 136 of FIG. 1A. For example, the method 500 may be performed by the second stage 150 of the encoder 136. The encoder includes a determinant inverse circuit, such as the determinant inverse circuit 204 or the determinant inverse circuit 300.

The method 500 includes applying a first circulant matrix to a first vector to generate a second vector, at 504. For example, the matrix multiplier circuit 302 may multiply the first vector 308 and the first circulant matrix 320 to generate the second vector 310.

The method 500 further includes squaring the first circulant matrix to generate a second circulant matrix, at 506. For example, the squaring circuit 306 may square the first circulant matrix 320 to generate the second circulant matrix 322.

The method 500 further includes applying the second circulant matrix to the second vector to generate a third vector, at 508. For example, the matrix multiplier circuit 302 may multiply the second circulant matrix 322 and the second vector 310 to generate the third vector 316. In an illustrative example, the second vector, the second circulant matrix, and the third vector are generated during an encoding process performed by the encoder 136 to encode the data 182, and the third vector includes a set of parity values associated with the data 182. For example, the third vector may include the third set of values 152.

Although various components depicted herein are illustrated as block components and described in general terms, such components may include one or more microprocessors, state machines, or other circuits configured to enable such components to perform one or more operations described herein. For example, the ECC engine 134 may represent physical components, such as hardware controllers, state machines, logic circuits, or other structures, to enable the ECC engine 134 to perform encoding operations and/or decoding operations.

Alternatively or in addition, one or more components described herein may be implemented using a microprocessor or microcontroller programmed to perform operations, such as one or more operations of the method 400 of FIG. 4, one or more operations of the method 500 of FIG. 5, or a combination thereof. Instructions executed by the controller 130 may be retrieved from the memory 104 or from a separate memory location that is not part of the memory 104, such as from a read-only memory (ROM).

The device 102 may be coupled to, attached to, or embedded within one or more accessing devices, such as within a housing of the access device 180. For example, the device 102 may be embedded within the access device 180 in accordance with a Joint Electron Devices Engineering Council (JEDEC) Solid State Technology Association Universal Flash Storage (UFS) configuration. To further illustrate, the device 102 may be integrated within an electronic device (e.g., the access device 180), such as a mobile telephone, a computer (e.g., a laptop, a tablet, or a notebook computer), a music player, a video player, a gaming device or console, a component of a vehicle (e.g., a vehicle console), an electronic book reader, a personal digital assistant (PDA), a portable navigation device, or other device that uses internal non-volatile memory.

In one or more other implementations, the device 102 may be implemented in a portable device configured to be selectively coupled to one or more external devices, such as a host device. For example, the device 102 may be removable from the access device 180 (i.e., “removably” coupled to the access device 180). As an example, the device 102 may be removably coupled to the access device 180 in accordance with a removable universal serial bus (USB) configuration.

The access device 180 may correspond to a mobile telephone, a computer (e.g., a laptop, a tablet, or a notebook computer), a music player, a video player, a gaming device or console, a component of a vehicle (e.g., a vehicle console), an electronic book reader, a personal digital assistant (PDA), a portable navigation device, another electronic device, or a combination thereof. The access device 180 may communicate via a controller, which may enable the access device 180 to communicate with the device 102. The access device 180 may operate in compliance with a JEDEC Solid State Technology Association industry specification, such as an embedded MultiMedia Card (eMMC) specification or a Universal Flash Storage (UFS) Host Controller Interface specification. Alternatively or in addition, the access device 180 may operate in compliance with one or more other specifications, such as a Secure Digital (SD) Host Controller specification as an illustrative example. Alternatively, the access device 180 may communicate with the device 102 in accordance with another communication protocol.

In some implementations, the system 100, the device 102, or the memory 104 may be integrated within a network-accessible data storage system, such as an enterprise data system, an NAS system, or a cloud data storage system, as illustrative examples. In these examples, the interface 170 may comply with a network protocol, such as an Ethernet protocol, a local area network (LAN) protocol, or an Internet protocol, as illustrative examples.

In some implementations, the device 102 may include a solid state drive (SSD). The device 102 may function as an embedded storage drive (e.g., an embedded SSD drive of a mobile device), an enterprise storage drive (ESD), a cloud storage device, a network-attached storage (NAS) device, or a client storage device, as illustrative, non-limiting examples. In some implementations, the device 102 may be coupled to the access device 180 via a network. For example, the network may include a data center storage system network, an enterprise storage system network, a storage area network, a cloud storage network, a local area network (LAN), a wide area network (WAN), the Internet, and/or another network.

To further illustrate, the device 102 may be configured to be coupled to the access device 180 as embedded memory, such as in connection with an embedded MultiMedia Card (eMMC®) (trademark of JEDEC Solid State Technology Association, Arlington, Va.) configuration, as an illustrative example. The device 102 may correspond to an eMMC device. As another example, the device 102 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The device 102 may operate in compliance with a JEDEC industry specification. For example, the device 102 may operate in compliance with a JEDEC eMMC specification, a JEDEC Universal Flash Storage (UFS) specification, one or more other specifications, or a combination thereof.

The memory 104 may include a resistive random access memory (ReRAM), a flash memory (e.g., a NAND memory, a NOR memory, a single-level cell (SLC) flash memory, a multi-level cell (MLC) flash memory, a divided bit-line NOR (DINOR) memory, an AND memory, a high capacitive coupling ratio (HiCR) device, an asymmetrical contactless transistor (ACT) device, or another flash memory), an erasable programmable read-only memory (EPROM), an electrically-erasable programmable read-only memory (EEPROM), a read-only memory (ROM), a one-time programmable memory (OTP), another type of memory, or a combination thereof. In a particular embodiment, the device 102 is indirectly coupled to an accessing device (e.g., the access device 180) via a network. For example, the device 102 may be a network-attached storage (NAS) device or a component (e.g., a solid-state drive (SSD) component) of a data center storage system, an enterprise storage system, or a storage area network. The memory 104 may include a semiconductor memory device.

Semiconductor memory devices include volatile memory devices, such as dynamic random access memory (“DRAM”) or static random access memory (“SRAM”) devices, non-volatile memory devices, such as resistive random access memory (“ReRAM”), magnetoresistive random access memory (“MRAM”), electrically erasable programmable read only memory (“EEPROM”), flash memory (which can also be considered a subset of EEPROM), ferroelectric random access memory (“FRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Alternatively, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this disclosure is not limited to the two dimensional and three dimensional exemplary structures described but cover all relevant memory structures within the spirit and scope of the disclosure as described herein and as understood by one of skill in the art. The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments. Those of skill in the art will recognize that such modifications are within the scope of the present disclosure.

The above-disclosed subject matter is to be considered illustrative, and not restrictive, and the appended claims are intended to cover all such modifications, enhancements, and other embodiments, that fall within the scope of the present disclosure. Thus, to the maximum extent allowed by law, the scope of the present invention is to be determined by the broadest permissible interpretation of the following claims and their equivalents, and shall not be restricted or limited by the foregoing detailed description.

What is claimed is:

1. An apparatus comprising:
an encoder configured to receive data and to encode the data based on an adjoint matrix to generate a codeword; and
a memory coupled to the encoder and configured to store the codeword.

2. The apparatus of claim 1, wherein the encoder includes:
a pre-processing circuit; and
matrix inverse circuitry coupled to the pre-processing circuit, the matrix inverse circuitry having a first stage and a second stage.

3. The apparatus of claim 2, wherein the first stage is configured to receive a first set of values from the pre-processing circuit and multiply the adjoint matrix and the first set of values to generate a second set of values.

4. The apparatus of claim 3, wherein the second stage is configured to receive the second set of values from the first stage and to generate a third set of values based on the second set of values and further based on a ring determinant.

5. The apparatus of claim 4, wherein the second stage is configured to multiply the ring determinant and the second set of values to generate the third set of values.

6. The apparatus of claim 4, wherein the third set of values includes parity values associated with the data.

7. The apparatus of claim 4, wherein the adjoint matrix and the ring determinant are based on a predefined square block matrix that is a subset of a parity check matrix, and wherein the encoder includes matrix inverse circuitry.

8. The apparatus of claim 7, further comprising a decoder configured to decode the codeword using the parity check matrix.

9. The apparatus of claim 1, wherein the encoder is further configured to encode the data based on a low-density parity check (LDPC) code.

10. The apparatus of claim 1, wherein the memory includes a non-volatile memory, and further comprising a controller coupled to the non-volatile memory.

11. The apparatus of claim 10, further comprising a data storage device that includes the controller and the memory.

12. The apparatus of claim 1, further comprising a communication device that includes or is coupled to the encoder and the memory.

13. A device comprising:
a first stage of matrix inverse circuitry, the first stage configured to receive a first set of values and to generate a second set of values based on the first set of values and further based on a ring adjoint matrix of a matrix; and
a second stage of the matrix inverse circuitry, the second stage configured to receive the second set of values and to generate a third set of values based on the second set of values and further based on a ring determinant of the matrix.

14. The device of claim 13, further comprising a pre-processing circuit configured to receive user data and to generate the first set of values based on the user data.

15. The device of claim 13, further comprising a low-density parity check (LDPC) encoder that includes the first stage and the second stage.

16. The device of claim 13, wherein each non-zero entry of the matrix corresponds to a cyclic permutation matrix.

17. The device of claim 16, wherein each cyclic permutation matrix has an order that is a power of two.

18. The device of claim 13, wherein the third set of values is equal to the first set of values multiplied by an inverse of the matrix, and wherein using the ring adjoint matrix enables generation of the third set of values without computing the inverse of the matrix.

19. The device of claim 13, wherein the third set of values is equal to the first set of values multiplied by an inverse of the matrix, and wherein using the ring adjoint matrix enables generation of the third set of values with less complexity than a direct computation of the first set of values multiplied by the inverse of the matrix.

20. The device of claim 13, wherein the second stage includes a determinant inverse circuit configured to perform a determinant inverse operation using the second set of values to generate the third set of values.

21. The device of claim 20, wherein the determinant inverse circuit is configured to operate based on a ring determinant inverse of a ring determinant matrix.

22. The device of claim 20, further comprising:
a parallel-to-serial circuit coupled to the first stage, the parallel-to-serial circuit configured to serialize the second set of values; and
a serial interface coupled to the parallel-to-serial circuit and coupled to the determinant inverse circuit.

23. The device of claim 13, wherein the second stage includes a set of determinant inverse circuits configured to receive the second set of values from the first stage.

24. The device of claim 23, further comprising a parallel interface coupled to the first stage and coupled to the set of determinant inverse circuits.

25. The device of claim 13, further comprising a data storage device that includes the matrix inverse circuitry.

26. A method comprising:
at an encoding device, performing
receiving data; and
encoding the data to generate a codeword, wherein the data is encoded based on an adjoint matrix.

27. The method of claim 26, further comprising storing the codeword at a memory that is coupled to the encoding device.

28. The method of claim 26, further comprising transmitting the codeword to a communication device via a communication network.

29. A method comprising:
at an encoder that includes a determinant inverse circuit, performing:
applying a first circulant matrix to a first vector to generate a second vector;
squaring the first circulant matrix to generate a second circulant matrix; and
applying the second circulant matrix to the second vector to generate a third vector.

30. The method of claim 29, wherein the second vector, the second circulant matrix, and the third vector are generated during an encoding process performed by the encoder to encode data, and wherein the third vector includes a set of parity values associated with the data.
